(19) United States
(12) Patent Application Publication
(10) Pub. No.: US 2003/0194614 A1
(43) Pub. Date: Oct. 16, 2003

(54) Method of forming a phase shift mask

(76) Inventor: Hsin-Di Lin, Cupertino, CA (US)

Correspondence Address: BRUCE H. TROXELL, SUITE 1404, 5205 LEESBURG PIKE, FALLS CHURCH, VA, 22041, US

(21) Appl. No.: 10/118,971

(22) Filed: Apr. 10, 2002

(51) Int. Cl. G03F 1/08; G03F 7/20; G03F 7/36; G03F 7/40

(52) U.S. Cl. 430/5; 430/296

(57) ABSTRACT

A method of forming a phase shift mask is disclosed. After providing a substrate with a shifter layer and a Cr layer, a first photoresist layer is formed on the Cr layer. Thereafter, a position of a shifter pattern is defined by using E-beam writing process and then a develop process is performed. After that, a first Cr pattern is formed by using an etching process to etch the Cr layer. After removing the first photoresist layer, the shifter pattern is formed by using an etching process to etch the shifter layer. After forming a second photoresist layer, an exposure process of conventional photolithography is performed by means of a boarder mask to define a position of a second Cr pattern. After performing a develop process, the second Cr pattern is formed by using an etching process to etch the first Cr pattern.

### BACKGROUND OF THE INVENTION

1. Field of the Invention

The present invention relates to a method of forming a phase shift mask and, more particularly, to a high-throughput and low-cost method of fabricating a phase shift mask.

2. Discussion of the Background

It is always required to achieve a finer pattern rule in the drive for higher integration and operating speeds in ULSI devices. The photo mask used in the pattern formation is also required to be of finer definition. A number of phase shift masks have thus been developed to meet this demand.

Please first refer to FIG. 1A to FIG. 1K, which illustrate cross-sectional diagrams of the conventional fabricating processes of a phase shift mask. A quartz substrate 10 with a shifter layer 12 and a Cr layer 14 is first provided. The shifter layer12 is provided on the quartz substrate 10, and the Cr layer 14 is provided on the shifter layer 12. After that, a first photoresist layer 16 is formed on the Cr layer 14, as shown in FIG. 1A.

Referring then to FIG. 1B, a position of a shifter pattern is defined by performing an electron beam writing process or a laser beam writing process to form the first photoresist pattern 18. A develop process is then preformed to remove the first photoresist pattern 18, as shown in FIG. 1C.

Referring then to FIG. 1D, a first Cr pattern 20 is formed by using a wet or dry etching process to etch the Cr layer 14. The first photoresist layer 16 is then removed, as shown in FIG. 1E. After that, the shifter pattern 22 is formed by using a wet or dry etching process through the first Cr pattern 20 to etch the shifter layer 12, as shown in FIG. 1F.

Referring then to FIG. 1G, a second photoresist layer 24 is formed on the quartz substrate 10 and the first Cr pattern 20. A laser beam writing process is then performed to form a second photoresist pattern 25 in order to define a position of a second Cr pattern, as shown in FIG. 1H.

Please refer now to FIG. 1I, which illustrates a cross-sectional diagram of removing the second photoresist pattern 25 by performing a develop process. Thereafter, second Cr pattern 26 is formed by using a wet or dry etching process through the residual second photoresist layer 24 to etch the first Cr pattern 20, as shown in FIG. 1J. Finally, the residual second photoresist layer 24 is removed, as shown in FIG. 1K.

As mentioned above, conventional fabrication of phase shift masks needs two writing processes, wherein the first writing process applies an electron beam writing process or a laser beam writing process, and the second writing process uses a laser beam writing process. It is necessary to notify that machines for performing the electron beam writing process or the laser beam writing process are very expensive (about 10 million US dollars) but with low throughput (2 to 3 hours for writing a mask). For this reason, the conventional fabrication of phase shift masks is high-cost and low-throughput.

### SUMMARY OF THE INVENTION

One object of the present invention relates to a method of forming a phase shift mask.

Another object of the present invention relates to a high-throughput and low-cost method of fabricating a phase shift mask.

A method of forming a phase shift mask is disclosed in the present invention. After providing a substrate with a shifter layer and a Cr layer, a first photoresist layer is formed on the Cr layer. Thereafter, a position of a shifter pattern is defined by using an electron beam writing process or a laser beam process, and then a develop process is performed. After that, a first Cr pattern is formed by using a dry or wet etching process to etch the Cr layer. After removing the first photoresist layer, the shifter pattern is formed by using a wet or dry etching process to etch the shifter layer. After forming a second photoresist layer, an exposure process of conventional photolithography is performed by means of a boarder mask to define a position of a second Cr pattern. After performing a develop process, the second Cr pattern is formed by using an etching process to etch the first Cr pattern.

The main advantage of the present invention is to lower fabrication cost and enhance fabrication throughput of phase shift masks. At the step of forming the second photoresist pattern 25 to define the position of a second Cr pattern 26, the high-cost and low-throughput laser beam writing process in the prior art is replaced by an exposure process of conventional photolithographic technique by using a boarder mask 50. The conventional photolithographic technique is performed by an ordinary conventional contact printer in a 5-inch or 6-inch IC fabrication plant.

The boarder mask contains a quartz substrate with a Cr frame layer, which is designed to accord with the position of the second Cr pattern. In order to prevent overlaying during the photolithographic process, the Cr frame layer is transferred from the second Cr pattern with sizing down in the range of 0 to 5 micron meter. The exposure process of the conventional photolithographic technique uses soft contact mode, hard contact, or vacuum contact.

The 5-inch or 6-inch contact printer costs only about 200,000 US dollars, which is much cheaper than the laser beam writing machine or the electron beam writing machine, which costs about 10 million US dollars. Therefore, the present invention is capable of largely lowering the fabrication cost of phase shift masks.

Furthermore, only about one (1) minute is needed to perform an exposure process by a 5-inch or 6-inch contact printer. On the other hand, two (2) to three (3) hours are needed to perform a laser beam writing process or an electron beam writing process. Therefore, the present invention is capable of largely enhancing the fabrication throughput of phase shift masks.

The present ULSI manufacture generally needs more than 30 photo masks, wherein five (5) or six (6) of them are phase shift masks. According to the present invention, those five (5) or six (6) phase shift masks can be formed by using only one boarder mask.

### BRIEF DESCRIPTION OF THE DRAWINGS

FIG. 1A to FIG. 1K schematically illustrate cross-sectional diagrams of the conventional fabrication process of a phase shift mask.

FIG. 2A to FIG. 2K schematically illustrate cross-sectional diagrams of the fabrication process of a phase shift mask according to the present invention.

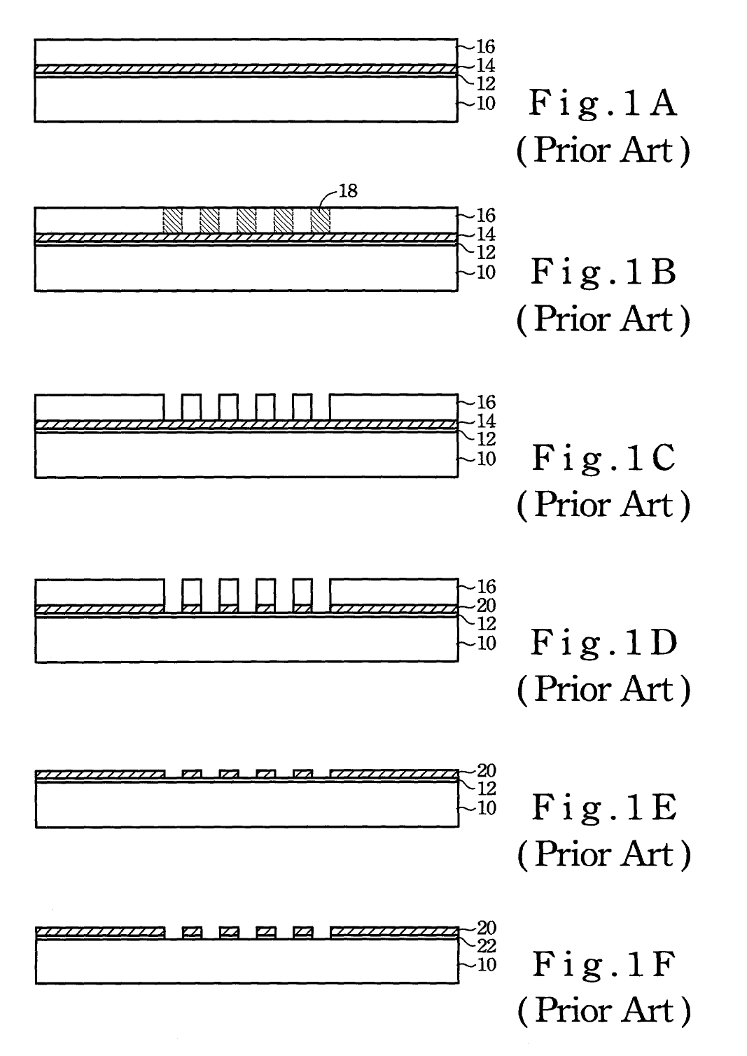

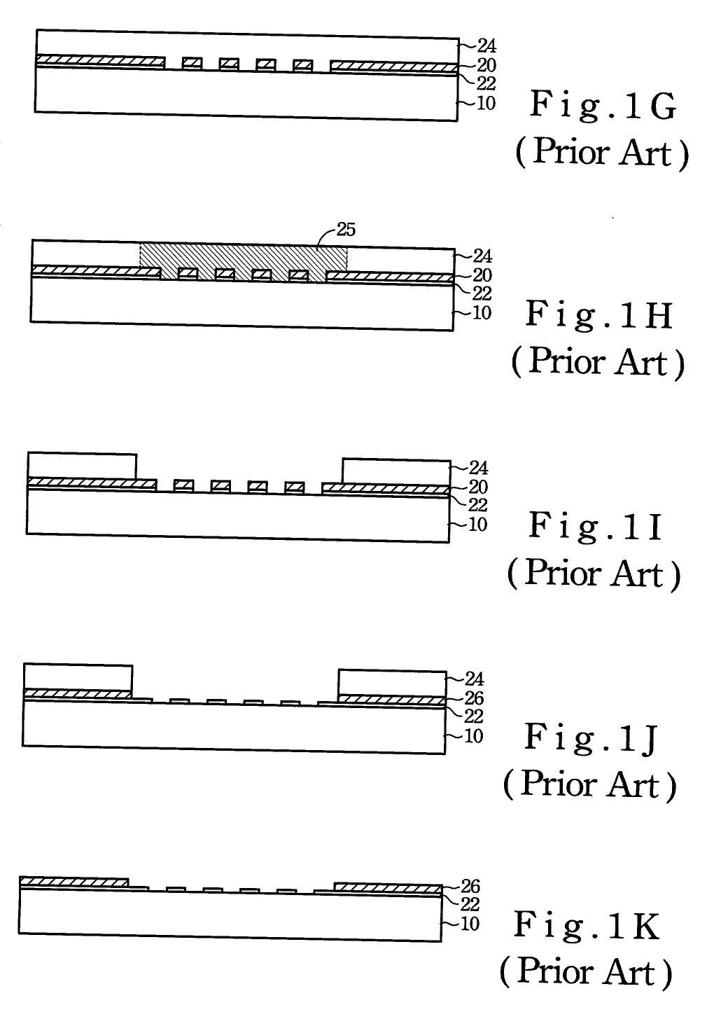

### DESCRIPTION OF THE PREFERRED EMBODIMENTS

The present invention relates to a method of forming a phase shift mask and, more particularly, to a high-throughput and low-cost method of fabricating a phase shift mask.

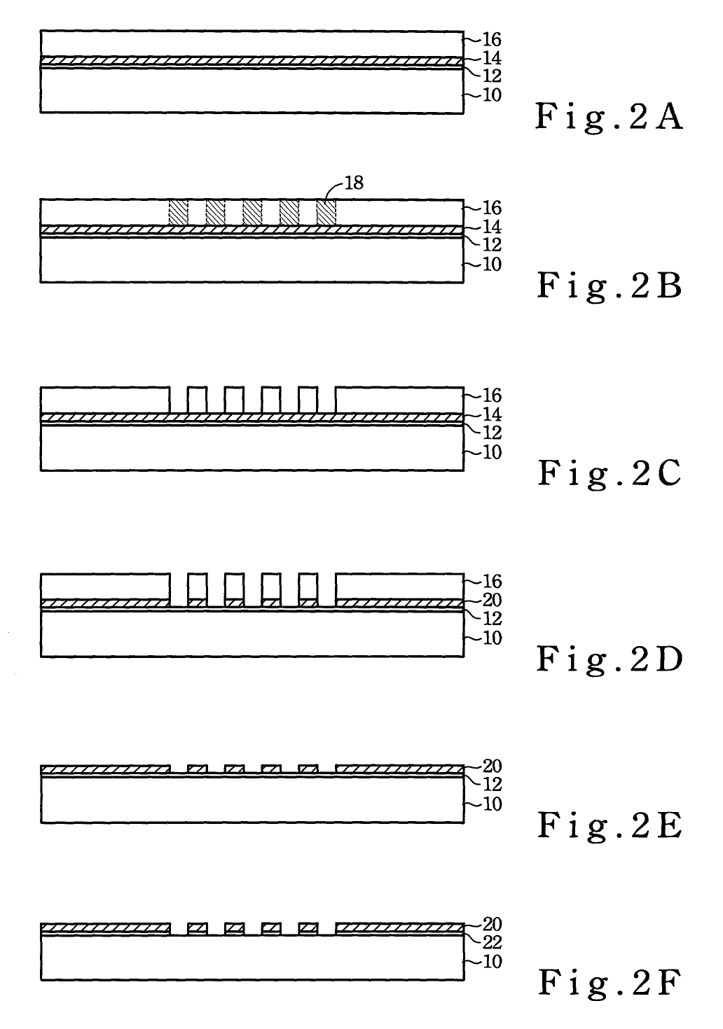

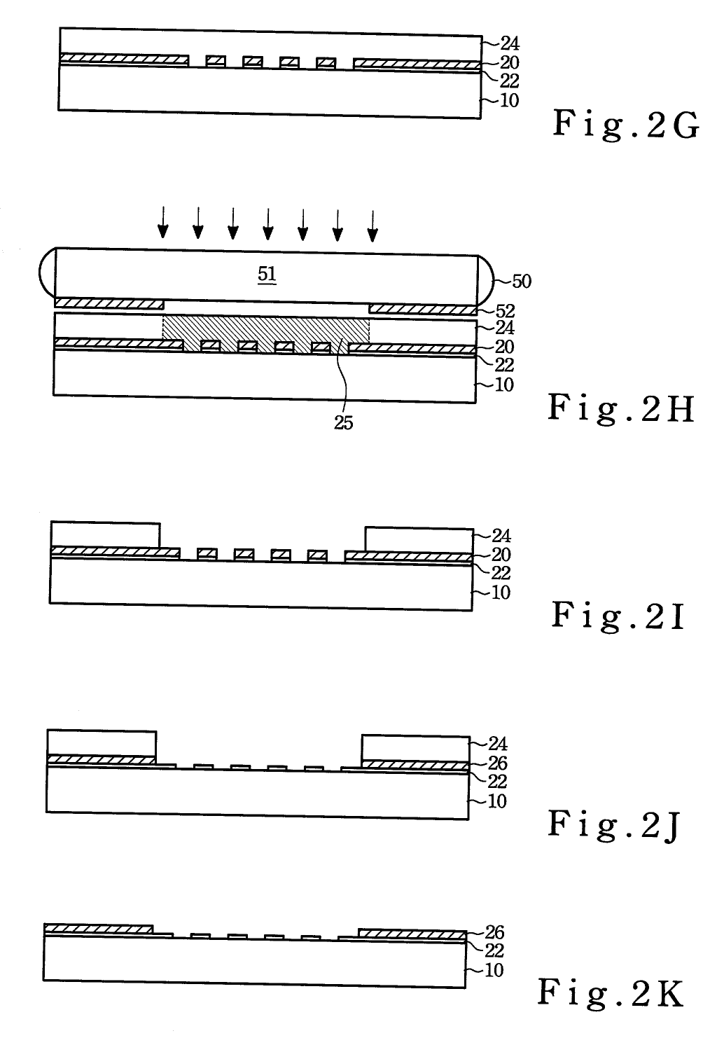

Please refer to FIG. 2A to FIG. 2K, which schematically illustrate cross-sectional diagrams of the fabrication processes of a phase shift mask according to the present invention.

A quartz substrate 10 with a shifter layer 12 and a Cr layer 14 is first provided. The shifter layer12 is provided on the quartz substrate10, and the Cr layer 14 is provided on the shifter layer 12. After that, a first photoresist layer 16 is formed on the Cr layer 14, as shown in FIG. 2A.

Referring then to FIG. 2B, a position of a shifter pattern is defined by using electron beam writing process or laser beam writing process to form the first photoresist pattern 18. A develop process is then preformed to remove the first photoresist pattern 18, as shown in FIG. 2C.

Referring then to FIG. 2D, a first Cr pattern 20 is formed by using a wet or dry etching process to etch the Cr layer 14. The first photoresist layer 16 is then removed, as shown in FIG. 2E. After that, the shifter pattern 22 is formed by using a wet or dry etching process through the first Cr pattern 20 to etch the shifter layer 12, as shown in FIG. 2F.

Next, a second photoresist layer 24 is formed on the quartz substrate 10 and the first Cr pattern 20, as shown in FIG. 2G.

Next, please refer to FIG. 2H, which is the key feature of the present invention. At the step of forming the second photoresist pattern 25 to define the position of a second Cr pattern 26, the high-cost and low-throughput laser beam writing process in the prior art is replaced by an exposure process of conventional photolithographic technique by using a boarder mask 50. The conventional photolithographic technique is performed by an ordinary conventional contact printer in a 5-inch or 6-inch IC fabrication plant.

The boarder mask 50 contains a quartz substrate 51 with a Cr frame layer 52, which is designed to accord with the position of the second Cr pattern 26. In order to prevent overlaying during the photolithographic process, the Cr frame layer 52 is transferred from the second Cr pattern 26 with sizing down in the range of 0 to 5 micron meter. The exposure process of the conventional photolithographic technique applies soft contact mode, hard contact, or vacuum contact.

Please refer now to FIG. 21, which illustrates a cross-sectional diagram of removing the second photoresist pattern 25 by performing a develop process. Thereafter, second Cr pattern 26 is formed by using a wet or dry etching process through the residual second photoresist layer 24 to etch the first Cr pattern20, as shown in FIG. 2J. Finally, the residual second photoresist layer 24 is removed, as shown in FIG. 2K.

The main advantage of the present invention is to lower manufacture cost and enhance manufacture throughput of phase shift masks. Related to the formation of the second photoresist pattern 25 to define the position of a second Cr pattern 26, the high-cost and low-throughput laser beam writing process in the prior art is replaced by an exposure process of conventional photolithographic technique by using a boarder mask 50. The conventional photolithographic technique is performed by a conventional contact printer of 5-inch or 6-inch technique.

The 5-inch or 6-inch contact printer costs only about 200,000 US dollars, which is much cheaper than the laser beam writing machine or the electron beam writing machine, which costs about 10 million US dollars. Therefore, the present invention is capable of largely lowering the manufacture cost of phase shift masks.

Furthermore, only about one (1) minute is needed to perform an exposure process by a 5-inch or 6-inch contact printer. On the other hand, two (2) to three (3) hours are needed to perform a laser beam writing process or an electron beam writing process. Therefore, the present invention is capable of largely enhancing the manufacture throughput of phase shift masks.

The present ULSI manufacture generally needs more than 30 photo masks, wherein five (5) or six (6) of them are phase shift masks. According to the present invention, those five (5) or six (6) phase shift masks can be formed by using only one boarder mask.

While the present invention has been described with regards to particular embodiments, it is recognized that additional variations of the present invention may be devised without departing from the inventive concept.

What is claimed is:

1. A method of forming a phase shift mask, comprising:
providing a substrate with a shifter layer and a Cr layer;
forming a first photoresist layer on said Cr layer;
defining a position of a shifter pattern by using an electron beam writing process and then performing a develop process;
forming a first Cr pattern by using an etching process to etch said Cr layer;
removing said first photoresist layer;
forming said shifter pattern by using an etching process to etch said shifter layer;
forming a second photoresist layer;
performing an exposure process of conventional photolithographic technique by means of a boarder mask to define a position of a second Cr pattern;
performing a develop process; and
forming said second Cr pattern by using an etching process to etch said first Cr pattern.

2. The method of claim 1, further comprising a step to remove said second photoresist layer after forming said second Cr pattern.

3. The method of claim 1, wherein said etching process is a wet etching process.

4. The method of claim 1, wherein said etching process is a dry etching process.

5. The method of claim 1, wherein said boarder mask contains a quartz substrate with a Cr frame layer, which is designed to accord with said position of said second Cr pattern.

6. The method of claim 5, wherein said Cr frame layer is transferred from said second Cr pattern with sizing down in the range of 0 to 5 micron meter.

7. The method of claim 1, wherein said exposure process of conventional photolithographic technique uses soft contact mode.

8. The method of claim 1, wherein said exposure process of conventional photolithographic technique uses hard contact mode.

9. The method of claim 1, wherein said exposure process of conventional photolithographic technique uses vacuum contact mode.

10. A method of forming a phase shift mask, comprising:
providing a substrate with a shifter layer and a Cr layer;
forming a first photoresist layer on said Cr layer;
defining a position of a shifter pattern by using a laser beam writing process and then performing a develop process;
forming a first Cr pattern by using an etching process to etch said Cr layer;
removing said first photoresist layer;
forming said shifter pattern by using an etching process to etch said shifter layer;
forming a second photoresist layer;
performing an exposure process of conventional photolithographic technique by means of a boarder mask to define a position of a second Cr pattern;
performing a develop process; and
forming said second Cr pattern by using an etching process to etch said first Cr pattern.

11. The method of claim 10, further comprising a step to remove said second photoresist layer after forming said second Cr pattern.

12. The method of claim 10, wherein said etching process is a wet etching process.

13. The method of claim 10, wherein said etching process is a dry etching process.

14. The method of claim 10, wherein said boarder mask contains a quartz substrate with a Cr frame layer, which is designed to accord with said position of said second Cr pattern.

15. The method of claim 14, wherein said Cr frame layer is transferred from said second Cr pattern with sizing down in the range of 0 to 5 micron meter.

16. The method of claim 10, wherein said exposure process of conventional photolithographic technique uses soft contact mode.

17. The method of claim 10, wherein said exposure process of conventional photolithographic technique uses hard contact mode.

18. The method of claim 10, wherein said exposure process of conventional photolithographic technique uses vacuum contact mode.
